(19) United States
(12) Patent Application Publication
(10) Pub. No.: US 2024/0033850 A1
(43) Pub. Date: Feb. 1, 2024

(54) LASER ANNEALING APPARATUS AND METHOD OF MANUFACTURING SUBSTRATE INCLUDING POLY-SI LAYER USING THE SAME

(71) Applicant: SAMSUNG DISPLAY CO., LTD., Yongin-si (KR)

(72) Inventors: Dongeon LIM, Yongin-si (KR); Kyongsik CHOI, Yongin-si (KR)

(21) Appl. No.: 18/227,803

(22) Filed: Jul. 28, 2023

(30) Foreign Application Priority Data
Jul. 29, 2022 (KR) 10-2022-0095027

(51) Int. Cl. B23K 26/06; B23K 26/352; B23K 26/035; B23K 26/073

(52) U.S. Cl. CPC B23K 26/0648; B23K 26/352; B23K 26/035; B23K 26/073; B23K 2101/34

(57) ABSTRACT

A laser annealing apparatus includes a first laser beam source emitting a first laser beam in a first direction, a second laser beam source disposed apart from the first laser beam source in a second direction perpendicular to the first direction and emitting a second laser beam in the first direction, a longitudinal optical system to which the first laser beam and the second laser beam are incident, and the longitudinal optical system expanding a width of each of the first laser beam and the second laser beam in the second direction, and a first wedge lens arranged between the first laser beam source and the longitudinal optical system to be in an optical path of the first laser beam and being rotatable within a preset angle with respect to a central axis in a third direction perpendicular to the first direction and the second direction.

This application claims priority to Korean Patent Application No. 10-2022-0095027, filed on Jul. 29, 2022, and all the benefits accruing therefrom under 35 U.S.C. § 119, the content of which in its entirety is herein incorporated by reference.

### BACKGROUND

### 1. Field

Embodiments relate to a laser annealing apparatus and a method of manufacturing a substrate including a polysilicon layer by the laser annealing apparatus, and more particularly, to a laser annealing apparatus capable of increasing energy efficiency and a method of manufacturing a substrate including a polysilicon layer by the laser annealing apparatus.

### 2. Description of the Related Art

In general, display apparatuses such as liquid crystal display apparatuses or organic light-emitting display apparatuses use thin-film transistors to control emission of respective pixels. Because such thin-film transistors include polysilicon, a process of forming a polysilicon layer on a substrate is performed during manufacturing of the display apparatuses. The polysilicon layer is formed by forming an amorphous silicon layer on the substrate and crystallizing the same. The crystallization may be performed by irradiating a laser beam onto the amorphous silicon layer.

### SUMMARY

However, in an existing laser annealing apparatus, laser beams from laser beam sources are not fully used during the crystallization of an amorphous silicon layer, and thus, the energy efficiency of the laser annealing apparatus is low.

The disclosure is to overcome various technical goals including the aforementioned one and provides a laser annealing apparatus capable of improving energy efficiency and a method of manufacturing a substrate including a polysilicon layer by the laser annealing apparatus. However, this is merely one of embodiments, and the scope of the disclosure is not limited thereto.

Additional features will be set forth in part in the description which follows and, in part, will be apparent from the description, or may be learned by practice of the presented embodiments of the disclosure.

In an embodiment of the disclosure, a laser annealing apparatus includes a first laser beam source emitting a first laser beam in a first direction, a second laser beam source disposed apart from the first laser beam source in a second direction perpendicular to the first direction, the second laser beam source emitting a second laser beam in the first direction, a longitudinal optical system to which the first laser beam and the second laser beam are incident, the longitudinal optical system expanding a width of each of the first laser beam and the second laser beam in the second direction, and a first wedge lens arranged between the first laser beam source and the longitudinal optical system to be in an optical path of the first laser beam. The first wedge lens is rotatable within a preset angle with respect to a central axis in a third direction perpendicular to the first direction and the second direction.

In an embodiment, a cross-section of the first wedge lens in a plane perpendicular to the third direction may have a wedge shape.

In an embodiment, in the cross-section of the first wedge lens in the plane perpendicular to the third direction, a width of a portion of the first wedge lens in a direction towards the second laser beam may be greater than a width of a portion of the first wedge lens in a direction away from the second laser beam.

In an embodiment, a location of the first laser beam in the second direction on a target surface may change as the first wedge lens is rotated.

In an embodiment, the laser annealing apparatus may further include a first beam cutter disposed between the longitudinal optical system and a target surface.

In an embodiment, the laser annealing apparatus may further include a first power meter disposed on a first surface of the first beam cutter in a direction towards the longitudinal optical system.

In an embodiment, when power of the first laser beam is measured by the first power meter, the first wedge lens may be rotated so that the power measured by the first power meter equals to zero.

In an embodiment, the first beam cutter may be disposed in a direction opposite to the second direction with respect to a center of the target surface.

In an embodiment, the laser annealing apparatus may further include a second wedge lens arranged between the second laser beam source and the longitudinal optical system to be in an optical path of the second laser beam, the second wedge lens being rotatable within a preset angle with respect to a central axis in the third direction.

In an embodiment, a cross-section of each of the first wedge lens and the second wedge lens in a plane perpendicular to the third direction may have a wedge shape.

In an embodiment, in the cross-section of the first wedge lens in the plane perpendicular to the third direction, a width of a portion of the first wedge lens in a direction towards the second laser beam may be greater than a width of a portion of the first wedge lens in a direction away from the second laser beam, and in the cross-section of the second wedge lens in the plane perpendicular to the third direction, a width of a portion of the second wedge lens in a direction towards the first laser beam may be greater than a width of a portion of the second wedge lens in a direction away from the first laser beam.

In an embodiment, a location of the first laser beam in the second direction on a target surface may change as the first wedge lens is rotated, and a location of the second laser beam in the second direction on the target surface may change as the second wedge lens is rotated.

In an embodiment, the laser annealing apparatus may further include a first beam cutter and a second beam cutter each disposed between the longitudinal optical system and a target surface.

In an embodiment, the laser annealing apparatus may further include a first power meter and a second power meter. The first power meter may be disposed on a first surface of the first beam cutter in a direction towards the longitudinal optical system, and the second power meter is disposed on a second surface of the second beam cutter in the direction towards the longitudinal optical system.

In an embodiment, when power of the first laser beam is measured by the first power meter, the first wedge lens may be rotated so that the power measured by the first power meter equals to zero, and when power of the second laser beam is measured by the second power meter, the second wedge lens may be rotated so that the power measured by the second power meter equals to zero.

In an embodiment, a rotation direction of the first wedge lens may be opposite to a rotation direction of the second wedge lens.

In an embodiment, the first beam cutter may be disposed in a direction opposite to the second direction with respect to a center of the target surface, and the second beam cutter may be disposed in the second direction with respect to the center of the target surface.

In an embodiment of the invention, there is provided a method of manufacturing a substrate including a polysilicon layer, the method including emitting a first laser beam in a first direction by a first laser beam source, emitting a second laser beam in the first direction by a second laser beam source that is apart from the first laser beam source in a second direction perpendicular to the first direction, and aligning a region on a target surface, where the first laser beam passing through a longitudinal optical system is incident, with a region on the target surface, where the second laser beam passing through the longitudinal optical system is incident, by rotating a first wedge lens which is arranged between the first laser beam source and the longitudinal optical system to be in an optical path of the first laser beam and is rotatable within a preset angle with respect to a central axis in a third direction perpendicular to the first direction and the second direction.

In an embodiment of the invention, there is provided a method of manufacturing a substrate including a polysilicon layer, the method including emitting a first laser beam in a first direction by a first laser beam source, emitting a second laser beam in the first direction by a second laser beam source that is apart from the first laser beam source in a second direction perpendicular to the first direction, and aligning a region on a target surface where the first laser beam passing through a longitudinal optical system is incident with a region on the target surface where the second laser beam passing through the longitudinal optical system is incident by rotating a first wedge lens or a second wedge lens, the first wedge lens being arranged between the first laser beam source and the longitudinal optical system to be in an optical path of the first laser beam and rotatable within a preset angle with respect to a central axis in a third direction perpendicular to the first direction and the second direction, the second wedge lens being arranged between the second laser beam source and the longitudinal optical system to be in an optical path of the second laser beam and rotatable within a preset angle with respect to the central axis in the third direction.

In an embodiment, the method may further include forming an amorphous silicon layer on the substrate, and irradiating, onto the amorphous silicon layer, the first laser beam and the second laser beam each having passed through the longitudinal optical system.

In an embodiment, a cross-section of the first wedge lens in a plane perpendicular to the third direction may have a wedge shape.

In an embodiment, in the cross-section of the first wedge lens in the plane perpendicular to the third direction, a width of a portion of the first wedge lens in a direction towards the second laser beam may be greater than a width of a portion of the first wedge lens in a direction away from the second laser beam.

In an embodiment, a location of the first laser beam in the second direction on the target surface may change as the first wedge lens is rotated.

In an embodiment, when power of the first laser beam is measured by a first power meter disposed on a first surface of a first beam cutter which is arranged between the longitudinal optical system and the target surface, the first surface in a direction towards the longitudinal optical system, the aligning may include rotating the first wedge lens so that the power measured by the first power meter equals to zero.

Other features and advantages other than those described above will become apparent from the following detailed description, claims and drawings for carrying out the disclosure.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic conceptual view showing an embodiment that a laser beam is irradiated onto an amorphous silicon layer by a laser annealing apparatus;

FIG. 2 is a schematic conceptual view of an embodiment of a laser annealing apparatus;

FIG. 3 is a schematic conceptual view of Comparative Example of a laser annealing apparatus;

FIGS. 4 and 5 are conceptual views showing optical path changes of laser beams by a wedge lens;

FIGS. 6 and 7 are schematic conceptual views of an embodiment of a laser annealing apparatus;

FIGS. 8 and 9 are schematic conceptual views of an embodiment of a laser annealing apparatus; and

FIGS. 10 and 11 are schematic conceptual views of an embodiment of a laser annealing apparatus.

### DETAILED DESCRIPTION

Reference will now be made in detail to embodiments, examples of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. The attached drawings for illustrating preferred embodiments of the disclosure are referred to in order to gain a sufficient understanding of the disclosure, the merits thereof, and the objectives accomplished by the implementation of the disclosure. The disclosure may, however, be embodied in many different forms and should not be construed as being limited to the embodiments set forth herein.

Hereinafter, embodiments of the disclosure will be described in detail with reference to the accompanying drawings. Like elements in the drawings denote like elements, and repeated descriptions thereof are omitted.

It will be understood that when a component, such as a layer, a film, a region, or a plate, is referred to as being “on” another component, the component can be directly on the other component or intervening components may be thereon. Sizes of components in the drawings may be exaggerated for convenience of explanation. In other words, since sizes and thicknesses of elements in the drawings are arbitrarily illustrated for convenience of explanation, the following the disclosure is not limited thereto.

In the following examples, the x-axis, the y-axis and the z-axis are not limited to three axes of the rectangular coordinate system, and may be interpreted in a broader sense. The x-axis, the y-axis, and the z-axis may be perpendicular to one another, or may represent different directions that are not perpendicular to one another, for example.

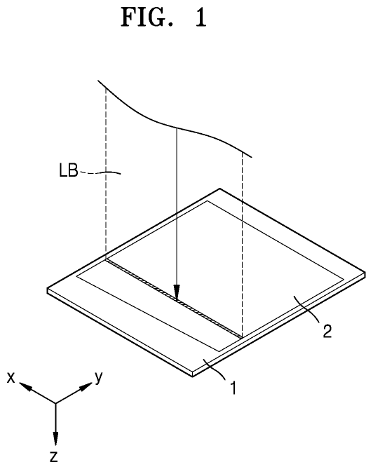

FIG. 1 is a schematic conceptual view showing an embodiment that a laser beam is irradiated onto an amorphous silicon layer 2 by a laser annealing apparatus. As shown in FIG. 1, a laser beam LB is irradiated onto the amorphous silicon layer 2 disposed on a substrate 1 seated on a stage (not shown). Accordingly, the amorphous silicon layer 2 is crystallized into a polysilicon layer. For reference, the laser beam LB may propagate in a first direction (a +z-axis direction) and have a line beam shape extending in a second direction (a +x direction) perpendicular to the first direction. The laser beam LB with a line beam shape having a long axis extending in the second direction (the +x direction) is moved in a third direction (a +y direction) perpendicular to the first direction and the second direction, thereby crystallizing the amorphous silicon layer 2 on the substrate 1.

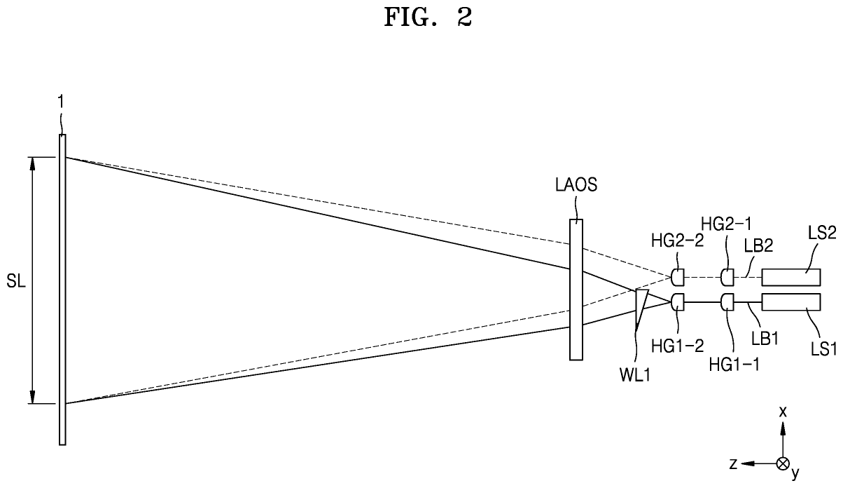

FIG. 2 is a schematic conceptual view of an embodiment of a laser annealing apparatus. As shown in FIG. 2, the laser annealing apparatus in the illustrated embodiment includes a first laser beam source LS1, a second laser beam source LS2, a longitudinal optical system LAOS, and a first wedge lens WL1.

The first laser beam source LS1 may emit a first laser beam LB1 in the first direction (a +z direction). The first laser beam source LS1 may be a fiber laser of which outputs may be adjusted over a wide range and which has low maintenance costs and high efficiency, for example. The second laser beam source LS2 may also emit a second laser beam LB2 in the first direction (the +z direction). The second laser beam source LS2 is apart from the first laser beam source LS1 in the second direction (the +x direction) perpendicular to the first direction. The second laser beam source LS2 may be a fiber laser, for example. For reference, FIG. 2 shows that an outer boundary of the first laser beam LB1 is indicated by a solid line, and an outer boundary of the second laser beam LB2 is indicated by a dashed line for convenience. The same description is applied to other drawings.

The first laser beam LB1 emitted from the first laser beam source LS1 and the second laser beam LB2 emitted from the second laser beam source LS2 are incident to the longitudinal optical system LAOS. The longitudinal optical system LAOS may increase a width of each of the first laser beam LB1 and the second laser beam LB2 in the second direction (the +x direction) to enable the first laser beam LB1 and the second laser beam LB2 to each have a line beam shape. To this end, the longitudinal optical system LAOS may include various lenses.

FIG. 2 schematically shows an optical system affecting only a length of each of the first laser beam LB1 and the second laser beam LB2 in the second direction (the +x direction), and a short axis optical system affecting a width of each of the first laser beam LB1 and the second laser beam LB2 in the third direction (the +y direction) is omitted for convenience. FIG. 2 is merely a schematic diagram, and thus, components such as a lens affecting only the length of each of the first laser beam LB1 and the second laser beam LB2 in the second direction (the +x direction) may be further included in addition to the longitudinal optical system LAOS of FIG. 2.

FIG. 2 shows that a 1-1 homogenizer HG1-1 and a 1-2 homogenizer HG1-2 are disposed between the longitudinal optical system LAOS and the first laser beam source LS1 and that a 2-1 homogenizer HG2-1 and a 2-2 homogenizer HG2-2 are disposed between the longitudinal optical system LAOS and the second laser beam source LS2. Such homogenizers may uniformize the energy of laser beams in portions of an irradiated surface to which the laser beams are irradiated.

The first wedge lens WL1 may be on an optical path of the first laser beam LB1 from the first laser beam source LS1. FIG. 2 shows that the first wedge lens WL1 is between the first laser beam source LS1 and the longitudinal optical system LAOS. As described above, the laser annealing apparatus may further include other components than the components shown in FIG. 2, and thus, the first wedge lens WL1 may be disposed between the longitudinal optical system LAOS and the other components.

The first wedge lens WL1 may be rotatable within a preset angle with respect to a central axis extending in the third direction (the +y direction) perpendicular to the first direction (the +z direction) and the second direction (the +x direction). A cross-section of the first wedge lens WL1 in a plane perpendicular to the third direction (the +y direction), that is, a zx plane, may have a wedge shape. In detail, in the cross-section of the first wedge lens WL1 in the zx plane, a width of a portion of the first wedge lens WL1 in a direction towards the second laser beam LB2 (the +x direction) may be greater than a width of a portion of the first wedge lens WL1 in a direction (a −x direction) away from the second laser beam LB2. As shown in FIG. 2, for example, a shape of the first wedge lens WL1 in the cross-section of the first wedge lens WL1 in the zx plane is substantially a triangle such as a right triangle and one of three sides may be in the direction towards the second laser beam LB2 (the +x direction). The first wedge lens WL1 may include a material such as fused silica, which is used when a general lens is manufactured.

The optical path of the first laser beam LB1 emitted from the first laser beam source LS1 changes as the first laser beam LB1 passes through the first wedge lens WL1. The first laser beam LB1 having passed through the first wedge lens WL1 and the second laser beam LB2 pass through the longitudinal optical system LAOS and then are incident to the irradiated surface of the substrate 1. In FIG. 2, an amorphous silicon layer, etc., are omitted for convenience. As shown in FIG. 2, a region of the substrate 1, where the second laser beam LB2 is irradiated, may be substantially the same as a region of the substrate 1 where the first laser beam LB1 having passed through the first wedge lens WL1 is irradiated. Accordingly, the amorphous silicon layer on the substrate 1 may be crystallized by reducing the energy loss. FIG. 2 shows a scan length SL that is a length of a region of the substrate 1, where the first laser beam LB1 and the second laser beam LB2 are simultaneously irradiated, in the second direction (the +x direction).

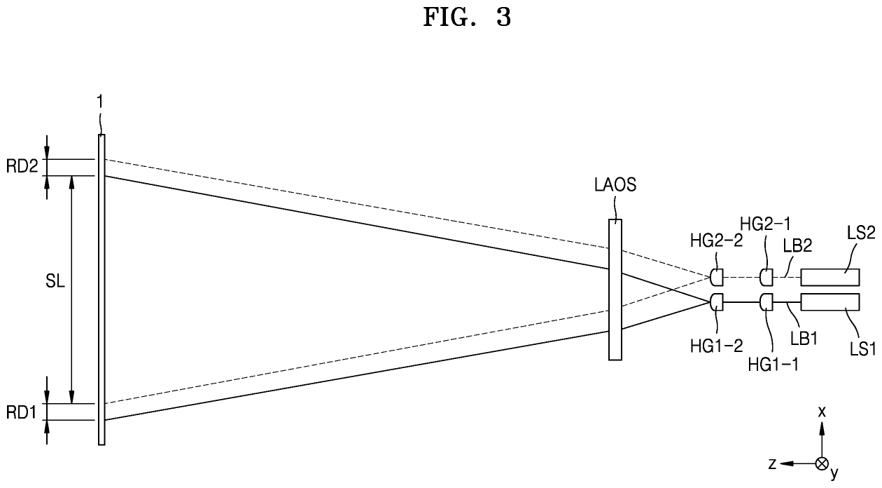

FIG. 3 is a schematic conceptual view of Comparative Example of a laser annealing apparatus, in which there is no first wedge lens WL1. Accordingly, the first laser beam LB1 emitted from the first laser beam source LS1 does not pass through the first wedge lens WL1 and is incident to the longitudinal optical system LAOS.

As described above, the second laser beam source LS2 is apart from the first laser beam source LS1 in the second direction (the +x direction). Therefore, as shown in FIG. 3, a region of the substrate 1, where the first laser beam LB1 from the first laser beam source LS1 is irradiated, is different from a region of the substrate 1, where the second laser beam LB2 from the second laser beam source LS2 is irradiated, in the second direction (the +x direction) that is a long-axis direction of the first laser beam LB1 and the second laser beam LB2. In this case, an effective irradiation region on the substrate 1 is a region where the first laser beam LB1 overlaps the second laser beam LB2. Therefore, FIG. 3 shows a scan length SL that is a length of a region of the substrate 1, where the first laser beam LB1 and the second laser beam LB2 are simultaneously irradiated, in the second direction (the +x direction).

As shown in FIG. 3, a first residual region RD1 and a second residual region RD2 are arranged on opposite sides of the effective irradiation region where the first laser beam LB1 overlaps the second laser beam LB2. The first laser beam LB1 is only irradiated to the first residual region RD1, and the second laser beam LB2 is only irradiated to the second residual region RD2. In this case, portions of the amorphous silicon layer of the substrate 1 in the first residual region RD1 and the second residual region RD2 are defective, and thus are not used during the manufacture of an electronic apparatus such as a display apparatus. In an alternative embodiment, the amorphous silicon layer does not exist in the first residual region RD1, where the first laser beam LB1 is only irradiated, and the second residual region RD2, where the second laser beam LB2 is only irradiated. In any case, the scan length SL, which is the length of the region of the substrate 1 where the first laser beam LB1 and the second laser beam LB2 are simultaneously irradiated in the second direction (the +x direction), is less than a length of the first laser beam LB1 in a long-axis direction (the +x direction) and a length of the second laser beam LB2 in the long-axis direction (the +x direction), and thus, the energy of the laser annealing apparatus may not be effectively used.

However, as described above with reference to FIG. 2, because the laser annealing apparatus includes the first wedge lens WL1, the first laser beam LB1 from the first laser beam source LS1 may pass through the first wedge lens WL1, and thus, the optical path of the first laser beam LB1 may change. As a result, the region of the substrate 1, where the second laser beam LB2 is irradiated, may be substantially the same as the region of the substrate 1, where the first laser beam LB1 having passed through the first wedge lens WL1, is irradiated. Accordingly, the amorphous silicon layer on the substrate 1 may be crystallized by reducing the energy loss in the laser annealing apparatus.

For reference, the scan length SL of FIG. 2, which is the length of the region of the substrate 1 where the first laser beam LB1 and the second laser beam LB2 are simultaneously irradiated in the second direction (the +x direction), is greater than the scan length SL of FIG. 3, which is the length of the region of the substrate 1 where the first laser beam LB1 and the second laser beam LB2 are simultaneously irradiated in the second direction (the x direction) when the first wedge lens WL1 does not exist. Therefore, when an amorphous silicon layer having a great area is crystallized, the laser annealing apparatus of FIG. 2 has more advantages over the laser annealing apparatus according to Comparative Example of FIG. 3.

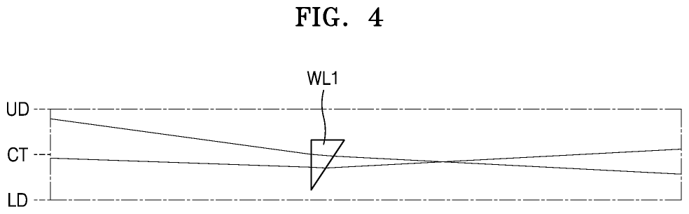

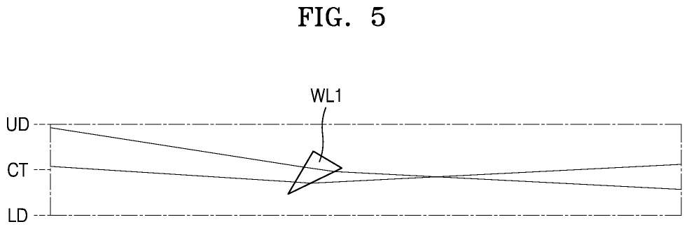

FIGS. 4 and 5 are conceptual views showing optical path changes of laser beams by the first wedge lens WL1. The difference between FIGS. 4 and 5 is the location of the first wedge lens WL1. Compared to the first wedge lens WL1 of FIG. 4, the first wedge lens WL1 of FIG. 5 is rotated at a predetermined angle in a clockwise direction with respect to a central axis extending in the third direction (the +y direction). Accordingly, compared to the first laser beam LB1 passing through the first wedge lens WL1 of FIG. 4, the first laser beam LB1 passing through the first wedge lens WL1 of FIG. 5 is relatively tilted upwards UD, not downwards LD, with respect to the center CT indicated on the left side of FIG. 5. That is, according to a location where the first wedge lens WL1 is rotated, that is, as the first wedge lens WL1 is rotated, the location of the first laser beam LB1 in the second direction (the +x direction) on a target surface may change. Thus, as a rotation angle of the first wedge lens WL1 is adjusted, the optical path of the first laser beam LB1 passing through the first wedge lens WL1 may be effectively and finely adjusted.

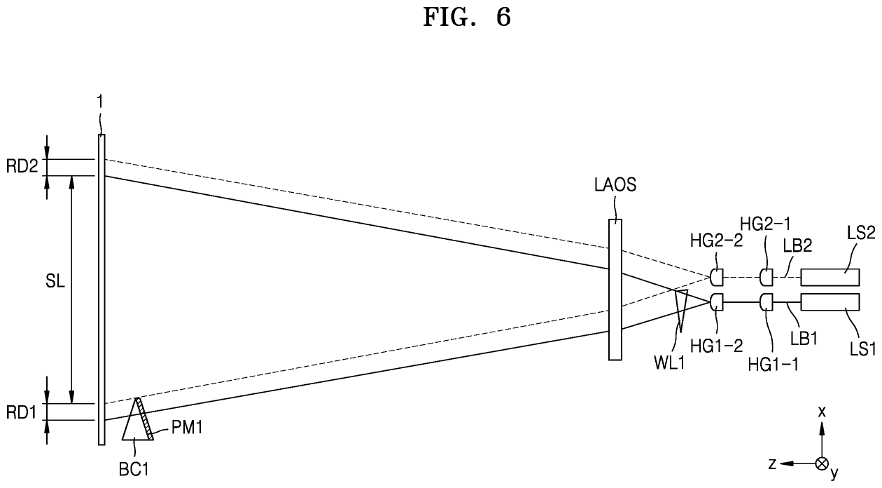

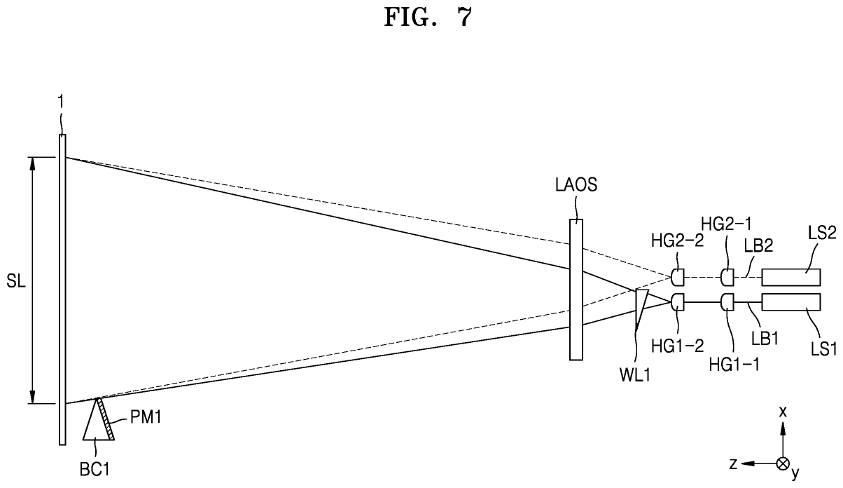

FIGS. 6 and 7 are schematic conceptual views of an embodiment of a laser annealing apparatus. The laser annealing apparatus in the illustrated embodiment further includes a first beam cutter BC1. The first beam cutter BC1 may be in a direction (a −x direction) opposite to the second direction (the +x direction) with respect to the center of a target surface, that is, a surface of the substrate 1.

As shown in FIG. 6, when the path of the first laser beam LB1 is not accurately corrected by the first wedge lens WL1, (when the first beam cutter BC1 does not exist,) the first residual region RD1, where the first laser beam LB1 is only irradiated, and the second residual region RD2, where the second laser beam LB2 is only irradiated, may be arranged on opposite sides of the effective irradiation region of the substrate 1 where the first laser beam LB1 and the second laser beam LB2 are simultaneously irradiated. The first beam cutter BC1 may block a predetermined portion of the first laser beam LB1, and thus, the first residual region RD1 does not exist on the substrate 1 in such a case.

In the above-described state, by rotating the first wedge lens WL1 at a predetermined angle in a clockwise direction with respect to the central axis extending in the third direction (the +y direction), to change the optical path of the first laser beam LB1 from the first laser beam source LS1 as the first laser beam LB1 passes through the first wedge lens WL1 as shown in FIG. 7, the region of the substrate 1 where the second laser beam LB2 is irradiated may become substantially the same as the region of the substrate 1 where the first laser beam LB1 passing through the first wedge lens WL1 is irradiated. In this case, the first beam cutter BC1 may hardly block the first laser beam LB1. Accordingly, the amorphous silicon layer on the substrate 1 may be crystallized by reducing the energy loss in the laser annealing apparatus.

As shown in FIGS. 6 and 7, the laser annealing apparatus in the illustrated embodiment may further include a first power meter PM1. The first power meter PM1 may be disposed on a first surface of the first beam cutter BC1 in a direction towards the longitudinal optical system LAOS (the −z direction). FIGS. 6 and 7 show that the first power meter PM1 covers an entirety of the first surface of the first beam cutter BC1, but the disclosure is not limited thereto. In an embodiment, the first power meter PM1 may be disposed around an end portion of the first surface of the first beam cutter BC1 in a direction towards the first laser beam LB1 (the +x direction). The first power meter PM1 may measure the power of laser beams incident to the first power meter PM1. In an embodiment, the first power meter PM1 may measure the brightness, etc., of the laser beams incident to the first power meter PM1, for example. That is, the term “power” may indicate brightness, etc., for example.

As shown in FIG. 6, while the path of the first laser beam LB1 is not accurately corrected by the first wedge lens WL1, (when the first beam cutter BC1 does not exist,) the first residual region RD1, where the first laser beam LB1 is only irradiated, and the second residual region RD2, where the second laser beam LB2 is only irradiated, are arranged on opposite sides of the effective irradiation region of the substrate 1 where the first laser beam LB1 and the second laser beam LB2 are simultaneously irradiated. The first beam cutter BC1 may block a predetermined portion of the first laser beam LB1, and thus, the first residual region RD1 does not exist on the substrate 1 in such a case. In this case, the first power meter PM1, which is on the first surface of the first beam cutter BC1 in the direction towards the longitudinal optical system LAOS (the −z direction), may measure the power of the first laser beam LB1 incident to the first power meter PM1. When a significant level of power of the first laser beam LB1 is measured by the first power meter PM1, it may be considered that the optical path of the first laser beam LB1 needs to be corrected by the first wedge lens WL1.

In the above state, by rotating the first wedge lens WL1 at a predetermined angle in a clockwise direction with respect to the central axis extending in the third direction (the +y direction) to change the optical path of the first laser beam LB1 from the first laser beam source LS1 as the first laser beam LB1 passes through the first wedge lens WL1 as shown in FIG. 7, the region of the substrate 1, where the second laser beam LB2 is irradiated, may become substantially the same as the region of the substrate 1, where the first laser beam LB1 passing through the first wedge lens WL1 is irradiated. In this case, the power of the first laser beam LB1 measured by the first power meter PM1, which is on the first surface of the first beam cutter BC1 in the direction towards the longitudinal optical system LAOS (the −z direction), may be substantially zero. When the power of the first laser beam LB1 measured by the first power meter PM1 is substantially zero, it may be determined that the optical path of the first laser beam LB1 is fixed substantially accurately by the first wedge lens WL1.

In the laser annealing apparatus in the illustrated embodiment, when the power of the first laser beam LB1 is measured by the first power meter PM1, the first wedge lens WL1 may be rotated to make the power measured by the first power meter PM1 be decreased or be substantially zero. Accordingly, the amorphous silicon layer on the substrate 1 may be crystallized by reducing the energy loss in the laser annealing apparatus.

It is described that no wedge lens is disposed between the second laser beam source LS2 and the longitudinal optical system LAOS, and in this case, a light-transmitting body that does not change an optical path of the second laser beam LB2 and includes the same material as that of the first wedge lens WL1 may be disposed between the second laser beam source LS2 and the longitudinal optical system LAOS. A size of the light-transmitting body is substantially the same as that of the first wedge lens WL1, and thus, the power, etc., of the first laser beam LB1 may be maintained to be substantially the same as the power, etc., of the second laser beam LB2 when the first laser beam LB1 and the second laser beam LB2 reach the irradiated surface.

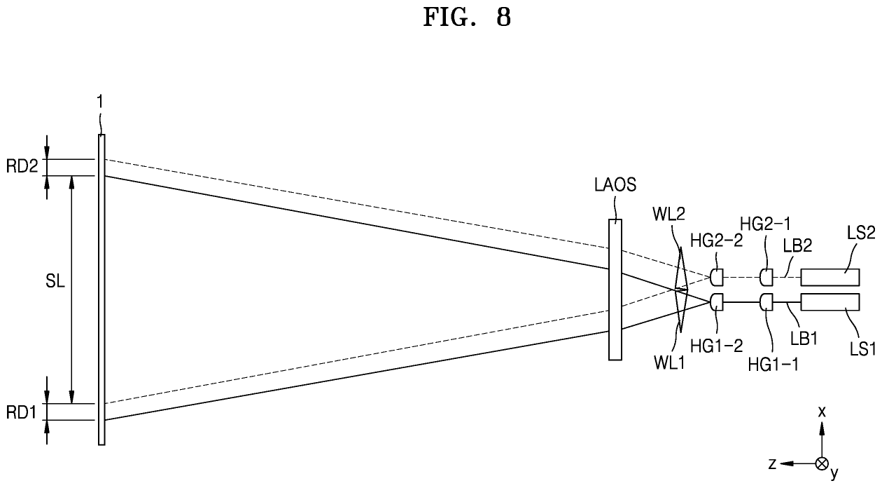

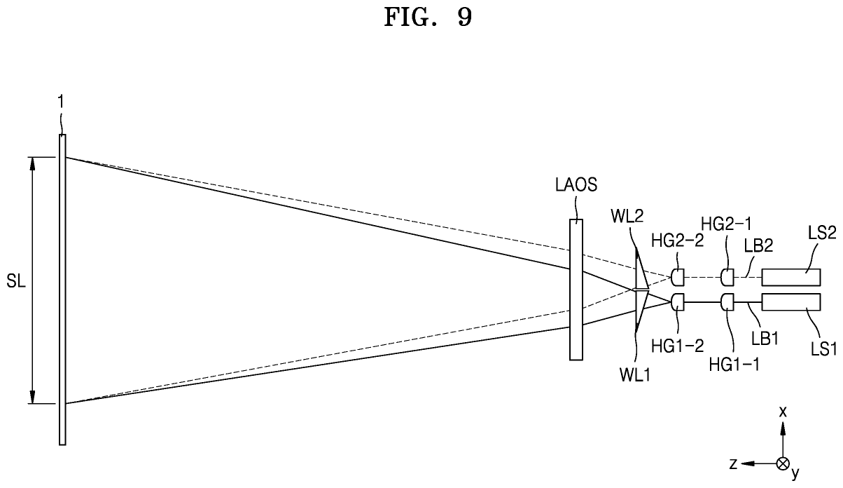

FIGS. 8 and 9 are schematic conceptual views of an embodiment of a laser annealing apparatus. The difference between the laser annealing apparatus of FIG. 2 and the laser annealing apparatus in the illustrated embodiment is that the laser annealing apparatus in the illustrated embodiment further includes a second wedge lens WL2. The second wedge lens WL2 may be disposed in the optical path of the second laser beam LB2 from the second laser beam source LS2. FIG. 8 shows that the second wedge lens WL2 is arranged between the second laser beam source LS2 and the longitudinal optical system LAOS. The laser annealing apparatus may further include other components than the components shown in FIG. 8, and thus, the second wedge lens WL2 may be arranged between the longitudinal optical system LAOS and the other components.

The second wedge lens WL2 may be rotatable within a preset angle with respect to a central axis extending in the third direction (the +y direction) perpendicular to the first direction (the +z direction) and the second direction (the +x direction). A cross-section of the second wedge lens WL2 in a plane perpendicular to the third direction (the +y direction), that is, the zx plane, may have a wedge shape. In detail, in the cross-section of the second wedge lens WL2 in the zx plane, a width of a portion of the second wedge lens WL2 in a direction towards the first laser beam LB1 (the −x direction) may be greater than a width of a portion of the second wedge lens WL2 in a direction (the +x direction) away from the first laser beam LB1. In an embodiment, as shown in FIG. 8, in the cross-section of the second wedge lens WL2 in the zx plane, a shape of the second wedge lens WL2 is substantially a triangle such as a right triangle, and one of three sides may be in the direction towards the first laser beam LB1 (the −x direction), for example. The second wedge lens WL2 may include a material such as fused silica, which is used when general lenses are manufactured.

The optical path of the second laser beam LB2 emitted from the second laser beam source LS2 changes as the second laser beam LB2 passes through the second wedge lens WL2. After the first laser beam LB1 having passed through the first wedge lens WL1 and the second laser beam LB2 having passed through the second wedge lens WL2 pass through the longitudinal optical system LAOS, the first laser beam LB1 and the second laser beam LB2 may be incident to the irradiated surface of the substrate 1. In FIG. 8, an amorphous silicon layer, etc., are omitted for convenience.

As shown in FIG. 8, while the paths of the first laser beam LB1 and the second laser beam LB2 are not accurately corrected by the first wedge lens WL1 and the second wedge lens WL2, the first residual region RD1, where the first laser beam LB1 is only irradiated, and the second residual region RD2, where the second laser beam LB2 is only irradiated, are arranged on opposite sides of the effective irradiation region of the substrate 1 where the first laser beam LB1 and the second laser beam LB2 are simultaneously irradiated. FIG. 8 shows a scan length SL that is a length of a region of the substrate 1 where the first laser beam LB1 and the second laser beam LB2 are simultaneously irradiated, in the second direction (the +x direction). A portion corresponding to the scan length SL may be an effective irradiation region.

When the first residual region RD1, where the first laser beam LB1 is only irradiated, and the second residual region RD2, where the second laser beam LB2 is only irradiated, are arranged on opposite sides of the effective irradiation region where the first laser beam LB1 overlaps the second laser beam LB2, portions of the amorphous silicon layer of the substrate 1 in the first residual region RD1 and the second residual region RD2 are defective, and thus are not used during the manufacture of an electronic apparatus such as a display apparatus. In an alternative embodiment, the amorphous silicon layer does not exist in the first residual region RD1, where the first laser beam LB1 is only irradiated, and the second residual region RD2, where the second laser beam LB2 is only irradiated. In any case, the scan length SL, which is the length of the region of the substrate 1 where the first laser beam LB1 and the second laser beam LB2 are simultaneously irradiated in the second direction (the +x direction), may be less than a length of the first laser beam LB1 in a long-axis direction (the +x direction) and a length of the second laser beam LB2 in the long-axis direction (the +x direction), and thus, the energy of the laser annealing apparatus may not be effectively used.

In the above-described state, by rotating the first wedge lens WL1 at a predetermined angle in a clockwise direction with respect to the central axis extending in the third direction (the +y direction) and the second wedge lens WL2 at a predetermined angle in a counterclockwise direction with respect to the central axis extending in the third direction (the +y direction) to change the optical path of the first laser beam LB1 from the first laser beam source LS1 and the optical path of the second laser beam LB2 from the second laser beam source LS2 as the first laser beam LB1 passes through the first wedge lens WL1 and the second laser beam LB2 passes through the second wedge lens WL2 as shown in FIG. 9, the region of the substrate 1, where the first laser beam LB1 passing through the first wedge lens WL1 is irradiated, may become substantially the same as the region of the substrate 1, where the second laser beam LB2 passing through the second wedge lens WL2 is irradiated. Accordingly, the amorphous silicon layer on the substrate 1 may be crystallized by reducing the energy loss in the laser annealing apparatus.

For reference, the scan length SL of FIG. 9, which is the length of the region of the substrate 1 where the first laser beam LB1 and the second laser beam LB2 are simultaneously irradiated in the second direction (the +x direction), may be greater than the scan length SL of FIG. 8, which is the length of the region of the substrate 1 where the first laser beam LB1 and the second laser beam LB2 are simultaneously irradiated in the second direction (the +x direction), in a state in which the optical paths of the first laser beam LB1 and the second laser beam LB2 are not appropriately adjusted by the first wedge lens WL1 and the second wedge lens WL2, respectively. Therefore, an amorphous silicon layer having a great area may be effectively crystallized by the laser annealing apparatus in the illustrated embodiment.

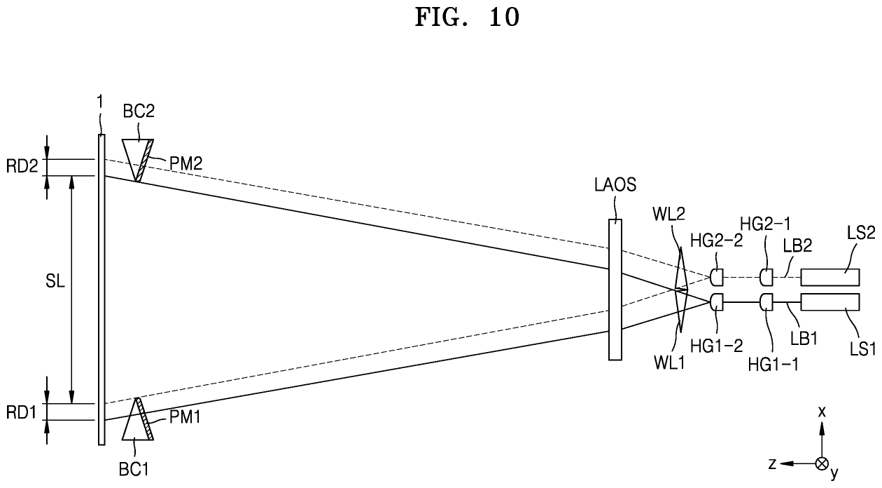

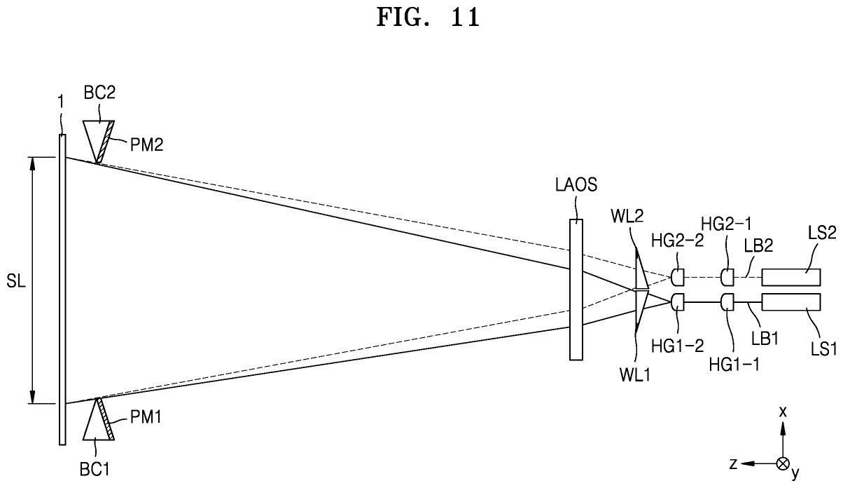

FIGS. 10 and 11 are schematic conceptual views of an embodiment of a laser annealing apparatus. Unlike the laser annealing apparatus of FIGS. 8 and 9, the laser annealing apparatus in the illustrated embodiment may further include a first beam cutter BC1 and a second beam cutter BC2. The first beam cutter BC1 may be in a direction (the −x direction) opposite to the second direction (the +x direction) with respect to the center of a target surface, that is, a surface of the substrate 1. The second beam cutter BC2 may be arranged in the second direction (the +x direction) with respect to the center of the target surface, that is, the surface of the substrate 1.

As shown in FIG. 10, while the paths of the first laser beam LB1 and the second laser beam LB2 are not accurately corrected by respectively using the first wedge lens WL1 and the second wedge lens WL2 (when the first beam cutter BC1 and the second beam cutter BC2 do not exist), the first residual region RD1, where the first laser beam LB1 is only irradiated, and the second residual region RD2, where the second laser beam LB2 is only irradiated, are arranged on opposite sides of the effective irradiation region on the substrate 1 where the first laser beam LB1 and the second laser beam LB2 are simultaneously irradiated. In such a case, the first beam cutter BC1 may block a predetermined portion of the first laser beam LB1, and the second beam cutter BC2 may block a predetermined portion of the second laser beam LB2 so that the first residual region RD1 and the second residual region RD2 do not exist on the substrate 1.

In this case, by rotating the first wedge lens WL1 at a predetermined angle in a clockwise direction with respect to the central axis extending in the third direction (the +y direction) and the second wedge lens WL2 at a predetermined angle in a counterclockwise direction with respect to the central axis extending in the third direction (the +y direction) to change the optical path of the first laser beam LB1 from the first laser beam source LS1 and the optical path of the second laser beam LB2 from the second laser beam source LS2 as the first laser beam LB1 passes through the first wedge lens WL1 and the second laser beam LB2 passes through the second wedge lens WL2 as shown in FIG. 11, the region of the substrate 1, where the first laser beam LB1 passing through the first wedge lens WL1 is irradiated, may become substantially the same as the region of the substrate 1, where the second laser beam LB2 passing through the second wedge lens WL2 is irradiated. In this case, the first beam cutter BC1 may hardly block the first laser beam LB1, and the second beam cutter BC2 may hardly block the second laser beam LB2. Accordingly, the amorphous silicon layer on the substrate 1 may be crystallized by reducing the energy loss in the laser annealing apparatus.

As shown in FIGS. 10 and 11, the laser annealing apparatus in the illustrated embodiment may further include a first power meter PM1 and a second power meter PM2. The first power meter PM1 may be disposed on a first surface of the first beam cutter BC1 in the direction towards the longitudinal optical system LAOS (the −z direction). The second power meter PM2 may be disposed on a second surface of the second beam cutter BC2 in the direction towards the longitudinal optical system LAOS (the −z direction). FIGS. 10 and 11 show that the first power meter PM1 covers an entirety of the first surface of the first beam cutter BC1 and the second power meter PM2 covers an entirety of the second surface of the second beam cutter BC2, but the disclosure is not limited thereto. In an embodiment, the first power meter PM1 may be disposed around an end portion of the first surface of the first beam cutter BC1 in the direction towards the first laser beam LB1 (the +x direction), and the second power meter PM2 may be disposed around an end portion of the second surface of the second beam cutter BC2 in the direction towards the second laser beam LB2 (the −x direction), for example.

The first power meter PM1 may measure the power of a laser beam incident to the first power meter PM1, and the second power meter PM2 may measure the power of a laser beam incident to the second power meter PM2. In an embodiment, the first power meter PM1 may measure the brightness, etc., of the laser beam incident to the first power meter PM1, and the second power meter PM2 may measure the brightness, etc., of the laser beam incident to the second power meter PM2, for example. That is, the term “power” may indicate brightness, etc., for example.

As shown in FIG. 10, when the paths of the first laser beam LB1 and the second laser beam LB2 are not accurately corrected by respectively using the first wedge lens WL1 and the second wedge lens WL2, (when the first beam cutter BC1 and the second beam cutter BC2 do not exist,) the first residual region RD1, where the first laser beam LB1 is only irradiated, and the second residual region RD2, where the second laser beam LB2 is only irradiated, are arranged on opposite sides of the effective irradiation region on the substrate 1 where the first laser beam LB1 and the second laser beam LB2 are simultaneously irradiated. In such a case, the first beam cutter BC1 may block a predetermined portion of the first laser beam LB1, and the second beam cutter BC2 may block a predetermined portion of the second laser beam LB2 so that the first residual region RD1 and the second residual region RD2 do not exist on the substrate 1. In this case, the first power meter PM1, which is on the first surface of the first beam cutter BC1 in the direction towards the longitudinal optical system LAOS (the −z direction), may measure the power of the first laser beam LB1 incident to the first power meter PM1. The second power meter PM2, which is on the second surface of the second beam cutter BC2 in the direction towards the longitudinal optical system LAOS, may measure the power of the second laser beam LB2 incident to the second power meter PM2. When a significant level of power of the first laser beam LB1 is measured by the first power meter PM1, it may be determined that the optical path of the first laser beam LB1 needs to be corrected by the first wedge lens WL1. As described, when a significant level of power of the second laser beam LB2 is measured by the second power meter PM2, it may be determined that the optical path of the second laser beam LB2 needs to be corrected by the second wedge lens WL2.

In the above state, by rotating the first wedge lens WL1 at a predetermined angle in a clockwise direction with respect to the central axis extending in the third direction (the +y direction) and the second wedge lens WL2 at a predetermined angle in a counterclockwise direction with respect to the central axis extending in the third direction (the +y direction) to change the optical path of the first laser beam LB1 from the first laser beam source LS1 and the optical path of the second laser beam LB2 from the second laser beam source LS2 as the first laser beam LB1 passes through the first wedge lens WL1 and the second laser beam LB2 passes through the second wedge lens WL2 as shown in FIG. 11, the region of the substrate 1, where the first laser beam LB1 passing through the first wedge lens WL1 is irradiated, may become substantially the same as the region of the substrate 1, where the second laser beam LB2 passing through the second wedge lens WL2 is irradiated. In this case, the power of the first laser beam LB1 that is measured by the first power meter PM1, which is on the first surface of the first beam cutter BC1 in the direction towards the longitudinal optical system LAOS (the −z direction), may be substantially zero, and the power of the second laser beam LB2 that is measured by the second power meter PM2, which is on the second surface of the second beam cutter BC2 in the direction towards the longitudinal optical system LAOS (the −z direction), may be substantially zero. When the power of the first laser beam LB1 measured by the first power meter PM1 and the power of the second laser beam LB2 measured by the second power meter PM2 are substantially zero, it may be determined that the optical paths of the first laser beam LB1 and the second laser beam LB2 are substantially accurately corrected by the first wedge lens WL1 and the second wedge lens WL2, respectively.

In the laser annealing apparatus in the illustrated embodiment, when the power of the first laser beam LB1 is measured by the first power meter PM1, the first wedge lens WL1 may be rotated to make the power measured by the first power meter PM1 be decreased or be substantially zero, and when the power of the second laser beam LB2 is measured by the second power meter PM2, the second wedge lens WL2 may be rotated in a direction opposite to the rotation direction of the first wedge lens WL1 to make the power measured by the second power meter PM2 be decreased or be substantially zero. Accordingly, the amorphous silicon layer on the substrate 1 may be crystallized by reducing the energy loss in the laser annealing apparatus.

The laser annealing apparatus is described, but the disclosure is not limited thereto. In an embodiment, a laser annealing method using the laser annealing apparatus is also included in the scope of the disclosure, and a method of manufacturing a substrate including a polysilicon layer by the laser annealing apparatus or a method of manufacturing a display apparatus is also included in the scope of the disclosure, for example.

In an embodiment, the method of manufacturing a substrate including a polysilicon layer includes emitting the first laser beam LB1 in the first direction (the +z direction) by the first laser beam source LS1 and emitting the second laser beam LB2 in the first direction (the +z direction) by the second laser beam source LS2 that is apart from the first laser beam source LS1 in the second direction (the +x direction) perpendicular to the first direction (the +z direction), for example. Then, as shown in FIG. 2, the first wedge lens WL1, which is arranged between the first laser beam source LS1 and the longitudinal optical system LAOS and rotatable within a preset angle with respect to the central axis extending in the third direction (the +y direction) perpendicular to the first direction (the +z direction) and the second direction (the +x direction), is rotated to be in the optical path of the first laser beam LB1. To this end, a region, where the first laser beam LB1 passes through the longitudinal optical system LAOS and is incident to the substrate 1 that is the target, may be aligned with a region, where the second laser beam LB2 passes through the longitudinal optical system LAOS and is incident to the substrate 1 that is the target.

The cross-sectional shape of the first wedge lens WL1 in a plane (the zx plane) perpendicular to the third direction (the +y direction) is the same as that described above with reference to FIG. 2, and a location change of the first laser beam LB1 in the second direction (the +x direction) according to the rotation of the first wedge lens WL1 is the same as that described above with reference to FIGS. 4 and 5. Also, the first beam cutter BC1 or the first power meter PM1 on the first surface of the first beam cutter BC1 may be used, which is the same as that described above with reference to FIGS. 6 and 7.

In the described state, the amorphous silicon layer 2 is formed on the substrate 1, and the first laser beam LB1 and the second laser beam LB2 having passed through the longitudinal optical system LAOS are irradiated onto the amorphous silicon layer 2. Accordingly, an amorphous silicon layer having a great area may be converted into a polysilicon layer by improving the energy efficiency of the laser annealing apparatus.

The method of manufacturing a substrate including a polysilicon layer includes emitting the first laser beam LB1 in the first direction (the +z direction) by the first laser beam source LS1 and emitting the second laser beam LB2 in the first direction (the +z direction) by the second laser beam source LS2 that is apart from the first laser beam source LS1 in the second direction (the +x direction) perpendicular to the first direction (the +z direction). Then, as shown in FIG. 8, the first wedge lens WL1, which is arranged between the first laser beam source LS1 and the longitudinal optical system LAOS to be in the optical path of the first laser beam LB1 and is rotatable within a preset angle with respect to the central axis extending in the third direction (the +y direction) perpendicular to the first direction (the +z direction) and the second direction (the +x direction), is rotated, and the second wedge lens WL2, which is arranged between the second laser beam source LS2 and the longitudinal optical system LAOS to be in the optical path of the second laser beam LB2 and is rotatable within a preset angle with respect to the central axis extending in the third direction (the +y direction), is rotated. To this end, a region, where the first laser beam LB1 passes through the longitudinal optical system LAOS and is incident to the substrate 1 that is the target, may be aligned with a region, where the second laser beam LB2 passes through the longitudinal optical system LAOS and is incident to the substrate 1 that is the target.

The cross-sectional shape of the first wedge lens WL1 and the cross-sectional shape of the second wedge lens WL2 in the plane (the zx plane) perpendicular to the third direction (the +y direction) are the same as those described above with reference to FIG. 8, and a location change of the first laser beam LB1 in the second direction (the +x direction) according to the rotation of the first wedge lens WL1 and a location change of the second laser beam LB2 in the direction (the −x direction) opposite to the second direction (the +x direction) according to the rotation of the second wedge lens WL2 are the same as those described above with reference to FIGS. 8 and 9. Also, the first beam cutter BC1 and the second beam cutter BC2 may be used, or the first power meter PM1 on the first surface of the first beam cutter BC1 and the second power meter PM2 on the second surface of the second beam cutter BC2 may be used, which is the same as those described above with reference to FIGS. 10 and 11.

In the described state, the amorphous silicon layer 2 is formed on the substrate 1, and the first laser beam LB1 and the second laser beam LB2 having passed through the longitudinal optical system LAOS are irradiated onto the amorphous silicon layer 2. Accordingly, an amorphous silicon layer having a great area may be converted into a polysilicon layer by improving the energy efficiency of the laser annealing apparatus.

After the amorphous silicon layer on the substrate 1 is formed into the polysilicon layer, a thin-film transistor is formed by the polysilicon layer, and then a display element, such as an organic light-emitting diode, which is electrically connected to the thin-film transistor, is formed, thereby manufacturing a display apparatus, etc.

According to the embodiments described above, a laser annealing apparatus capable of improving energy efficiency and a method of manufacturing a substrate including a polysilicon layer by the laser annealing apparatus may be realized. However, the scope of the disclosure is not limited by the effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A laser annealing apparatus comprising:
a first laser beam source which emits a first laser beam in a first direction;
a second laser beam source which is disposed apart from the first laser beam source in a second direction perpendicular to the first direction and emits a second laser beam in the first direction;
a longitudinal optical system to which the first laser beam and the second laser beam are incident, the longitudinal optical system expanding a width of each of the first laser beam and the second laser beam in the second direction; and
a first wedge lens arranged between the first laser beam source and the longitudinal optical system to be disposed in an optical path of the first laser beam,
wherein the first wedge lens is rotatable within a preset angle with respect to a central axis in a third direction perpendicular to the first direction and the second direction.

2. The laser annealing apparatus of claim 1, wherein a cross-section of the first wedge lens in a plane perpendicular to the third direction has a wedge shape.

3. The laser annealing apparatus of claim 1, further comprising a first beam cutter disposed between the longitudinal optical system and a target surface.

4. The laser annealing apparatus of claim 3, further comprising a first power meter disposed on a first surface of the first beam cutter in a direction towards the longitudinal optical system.

5. The laser annealing apparatus of claim 1, further comprising a second wedge lens arranged between the second laser beam source and the longitudinal optical system to be disposed in an optical path of the second laser beam, the second wedge lens being rotatable within a preset angle with respect to a central axis in the third direction.

6. The laser annealing apparatus of claim 5, wherein a cross-section of each of the first wedge lens and the second wedge lens in a plane perpendicular to the third direction has a wedge shape.

7. The laser annealing apparatus of claim 5, further comprising a first beam cutter and a second beam cutter each disposed between the longitudinal optical system and a target surface.

8. The laser annealing apparatus of claim 7, further comprising a first power meter and a second power meter, wherein the first power meter is disposed on a first surface of the first beam cutter in a direction towards the longitudinal optical system, and the second power meter is disposed on a second surface of the second beam cutter in the direction towards the longitudinal optical system.

9. A method of manufacturing a substrate comprising a polysilicon layer, the method comprising:
emitting a first laser beam in a first direction by a first laser beam source;
emitting a second laser beam in the first direction by a second laser beam source that is apart from the first laser beam source in a second direction perpendicular to the first direction; and
aligning a region on a target surface where the first laser beam passing through a longitudinal optical system is incident, with a region on the target surface where the second laser beam passing through the longitudinal optical system is incident, by rotating a first wedge lens which is arranged between the first laser beam source and the longitudinal optical system to be in an optical path of the first laser beam and is rotatable within a preset angle with respect to a central axis in a third direction perpendicular to the first direction and the second direction.

10. The method of claim 9, further comprising:
forming an amorphous silicon layer on the substrate; and
irradiating, onto the amorphous silicon layer, the first laser beam and the second laser beam
each having passed through the longitudinal optical system.

11. The method of claim 9, wherein a cross-section of the first wedge lens in a plane perpendicular to the third direction has a wedge shape.

12. The method of claim 11, wherein, in the cross-section of the first wedge lens in the plane perpendicular to the third direction, a width of a portion of the first wedge lens in a direction towards the second laser beam is greater than a width of a portion of the first wedge lens away from the second laser beam.

13. The method of claim 9, wherein a location of the first laser beam in the second direction on the target surface changes as the first wedge lens is rotated.

14. The method of claim 9, wherein the aligning comprises, when power of the first laser beam is measured by a first power meter disposed on a first surface of a first beam cutter which is arranged between the longitudinal optical system and the target surface, the first surface in a direction towards the longitudinal optical system, rotating the first wedge lens so that the power measured by the first power meter equals to zero.

15. A method of manufacturing a substrate comprising a polysilicon layer, the method comprising:
emitting a first laser beam in a first direction by a first laser beam source;
emitting a second laser beam in the first direction by a second laser beam source that is apart from the first laser beam source in a second direction perpendicular to the first direction; and
aligning a region on a target surface where the first laser beam passing through a longitudinal optical system is incident with a region on the target surface where the second laser beam passing through the longitudinal optical system is incident by rotating a first wedge lens or a second wedge lens,
wherein
the first wedge lens is arranged between the first laser beam source and the longitudinal optical system to be in an optical path of the first laser beam and rotatable within a preset angle with respect to a central axis in a third direction perpendicular to the first direction and the second direction, and
the second wedge lens is arranged between the second laser beam source and the longitudinal optical system to be in an optical path of the second laser beam and rotatable within a preset angle with respect to the central axis in the third direction.

16. The method of claim 15, further comprising forming an amorphous silicon layer on the substrate; and
irradiating, onto the amorphous silicon layer, the first laser beam and the second laser beam each having passed through the longitudinal optical system.

17. The method of claim 15, wherein a cross-section of the first wedge lens in a plane perpendicular to the third direction has a wedge shape.

18. The method of claim 17, wherein, in the cross-section of the first wedge lens in the plane perpendicular to the third direction, a width of a portion of the first wedge lens in a direction towards the second laser beam is greater than a width of a portion of the first wedge lens in a direction away from the second laser beam.

19. The method of claim 15, wherein a location of the first laser beam in the second direction on the target surface changes as the first wedge lens is rotated.

20. The method of claim 15, wherein, when power of the first laser beam is measured by a first power meter disposed on a first surface of a first beam cutter which is arranged between the longitudinal optical system and the target surface, the first surface in a direction towards the longitudinal optical system, the aligning comprises rotating the first wedge lens so that the power measured by the first power meter equals to zero.
